(19) United States
(12) Patent Application Publication
(10) Pub. No.: US 2026/0342343 A1
(43) Pub. Date: Oct. 29, 2026

(54) ELECTRONIC DEVICE AND METHOD OF DRIVING ELECTRONIC DEVICE

(71) Applicant: Samsung Display Co., Ltd., Yongin-Si (KR)

(72) Inventors: TAEGON IM, Yongin-si (KR); Gyeongpil JANG, Yongin-si (KR); TAEYOUNG JIN, Yongin-si (KR)

(21) Appl. No.: 19/574,442

(22) Filed: Mar. 23, 2026

(30) Foreign Application Priority Data
Apr. 23, 2025 (KR) 10-2025-0052746

(51) Int. Cl. H03L 7/099; G09G 5/00

(52) U.S. Cl. CPC H03L 7/0992; G09G 5/008; G09G 2310/08

(57) ABSTRACT

An electronic device includes a display panel displaying an image on a frame-by-frame basis, and a driving controller receiving image data including command data. The driving controller includes a memory unit, a generation unit generating a command synchronization signal in response to the command data, a clock unit selecting a synchronization signal, a counter unit counting clock pulses of the synchronization signal, a comparison unit calculating a command count value and comparing the command count value with a threshold value, and an insertion unit determining a driving frequency of the frame based on the comparison of the command count value and the threshold value. The driving controller outputs source data based on the image data stored in a memory unit when the command count value is greater than the threshold value.

### CROSS-REFERENCE TO RELATED APPLICATIONS

This application claims priority under 35 U.S.C. § 119 to Korean Patent Application No. 10-2025-0052746, filed on Apr. 23, 2025, the entire contents of which are hereby incorporated by reference.

### BACKGROUND

The present disclosure herein relates to an electronic device having improved afterimages and a method of driving the electronic device.

Various electronic devices, which are applicable to multimedia devices, such as a television, a mobile phone, a tablet computer, a navigation system, and a game console, have been developed.

As the application fields of such display devices diversify, the types of display layers for displaying an image on the display devices have also been developed to meet the various display requirements.

Recently, an electronic device may include a light-emitting display layer, which include an organic light-emitting display layer or a quantum-dot light-emitting display layer, and the like.

### SUMMARY

The present disclosure provides an electronic device having improved afterimages and a method of driving the electronic device.

According to an embodiment of the inventive concept, an electronic device includes a display panel configured to display an image on a frame-by-frame basis, and a driving controller configured to drive the display panel and receive image data including command data. The driving controller includes a memory unit configured to store the image data based on the command data, a generation unit configured to generate a command synchronization signal in response to the command data, a clock unit configured to select a synchronization signal among a plurality of synchronization signals, a counter unit configured to count clock pulses of the synchronization signal and output a count value, a comparison unit configured to calculate a command count value and compare the command count value with a threshold value, , and an insertion unit configured to determine a driving frequency of the frame based on the comparison of the command count value and the threshold value. The command count value is calculated by counting a number of the clock pulses of the synchronization signal during a period of the command synchronization signal. The driving controller is configured to output source data based on the image data stored in the memory unit when the command count value is greater than the threshold value.

In an embodiment, the plurality of synchronization signals may include a basic synchronization signal, a vertical synchronization signal, an emission synchronization signal, a horizontal synchronization signal, and an oscillator synchronization signal, and each of the plurality of synchronization signals may have a period different from one another.

In an embodiment, the display panel may include a pixel, and the emission synchronization signal may control an emission of the pixel.

In an embodiment, the driving controller may further include an oscillator, and the oscillator synchronization signal may control a logic operation and timing based on a clock signal generated from the oscillator.

In an embodiment, the command synchronization signal may be configured to output a clock pulse when the command data is input.

In an embodiment, the image data may include a first section, a second section, a third section, a fourth section, and a fifth section, which are arranged sequentially, and the first section may indicate a start of the frame.

In an embodiment, the second section may be configured to serve to prepare the frame.

In an embodiment, the command data may be provided in the third section.

In an embodiment, information representing the image may be provided in the fourth section.

In an embodiment, the fifth section may be configured to serve to stabilize the frame.

In an embodiment, the source data of the frame may include a first source section, a second source section, a third source section, and a fourth source section, which are arranged sequentially, and the first source section may indicate a start of the frame in response to a clock pulse of the vertical synchronization signal.

In an embodiment, the second source section may be configured to prepare the frame.

In an embodiment, information representing the image may be provided in the third source section.

In an embodiment, the fourth source section may be configured to stabilize the frame. The frame may include a first frame having a first driving frequency and a second frame having a second driving frequency different from the first driving frequency, and a length of the fourth source section provided in the first frame may be different from a length of the fourth source section provided in the second frame.

According to an embodiment of the inventive concept, a method of driving an electronic device includes storing image data in a memory unit, generating a command synchronization signal based on command data, selecting a synchronization signal and counting clock pulses of the synchronization signal, calculating a command count value and comparing the command count value with a threshold value, and determining a driving frequency of the frame. The electronic device includes a display panel configured to display an image on a frame-by-frame basis, and a driving controller configured to drive the display panel and receive the image data including the command data.

In an embodiment, the command synchronization signal may be configured to output a clock pulse when the command data is input.

In an embodiment, the determining of a driving frequency of the frame may further include outputting source data based on the image data stored in the memory unit when the command count value is greater than the threshold value.

In an embodiment, the method may further include comparing a value stored in the memory with a value which is newly input into the memory unit.

In an embodiment, the determining of a driving frequency of the frame may be performed when the value stored in the memory is not equal to the value which is newly input into the memory unit.

In an embodiment, the driving controller may output source data based on the image data stored in the memory unit when the command count value is greater than the threshold value or a value stored in the memory is not equal to a value which is newly input.

### BRIEF DESCRIPTION OF THE FIGURES

The accompanying drawings are included to provide a further understanding of the inventive concept, and illustrate embodiments of the inventive concept together with the description to explain features of the inventive concept.

FIG. 1 is a block diagram illustrating an electronic device according to an embodiment.

FIG. 2 illustrates perspective views of electronic devices according to various embodiments.

FIG. 3 is a block diagram illustrating a display device according to an embodiment of the inventive concept.

FIG. 4 illustrates a diving frequency, image data, source data, and synchronization signals associated with a driving operation of an electronic device according to an embodiment of the inventive concept.

FIG. 5 is a block diagram illustrating a driving controller according to an embodiment of the inventive concept.

FIG. 6 is a flowchart illustrating a method of driving an electronic device according to an embodiment of the inventive concept.

### DETAILED DESCRIPTION

In this specification, it will be understood that when an element (or a region, a layer, a portion, or the like) is referred to as being "on", "connected to" or "coupled to" another element, it may be directly disposed on or connected to, or indirectly on, connected to or coupled to the other element with an intervening element disposed therebetween.

Like reference numerals or symbols refer to like elements throughout the specification. In the drawings, the thickness, ratio, and size of the elements are exaggerated for effectively describing the technical features of the inventive concept. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

In addition, the terms, such as "below", “under”, "on the lower side", "above", “over”, "on the upper side", or the like, may be used to describe the spatial relationships between the elements illustrated in the drawings. These terms are relative concepts and are described on the basis of the directions indicated in the drawings.

It will be further understood that the terms "comprises, includes, has" and/or its variation such as "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless defined otherwise, all terms (including technical and scientific terms) used herein have the same meaning as commonly understood by one of ordinary skill in the art to which the inventive concept pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

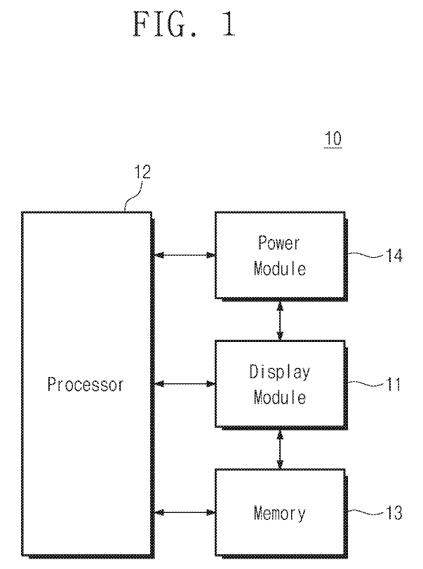

FIG. 1 is a block diagram illustrating an electronic device according to an embodiment.

Referring to FIG. 1, an electronic device 10 according to an embodiment may include a display module 11, a processor 12, a memory 13, and a power module 14.

The processor 12 may include at least one among a central processing unit (CPU), an application processor (AP), a graphic processing unit (GPU), a communication processor (CP), an image signal processor (ISP), and a controller.

The memory 13 may store data information required for an operation of the processor 12 or the display module 11. When the processor 12 executes an application stored in the memory 13, an image data signal and/or an input control signal may be transferred to the display module 11, and the display module 11 may process the received signal and output image corresponding to the received signal through a display screen.

The power module 14 may include a power supply module, such as a power adaptor or a battery device, and a power conversion module that converts power supplied from the power supply module to generate power required for an operation of the electronic device 10.

At least one of individual components of the electronic device 10 may be included in a display device according to an embodiment described above. Additionally, among individual modules that are functionally included in a single module, some may be included in the display device, and others may be provided separately from the display device. For example, while the display device may include the display module 11 and the processor 12, the memory 13 and the power module 14 may be provided in the form of separate components in the electronic device 10 other than the display device.

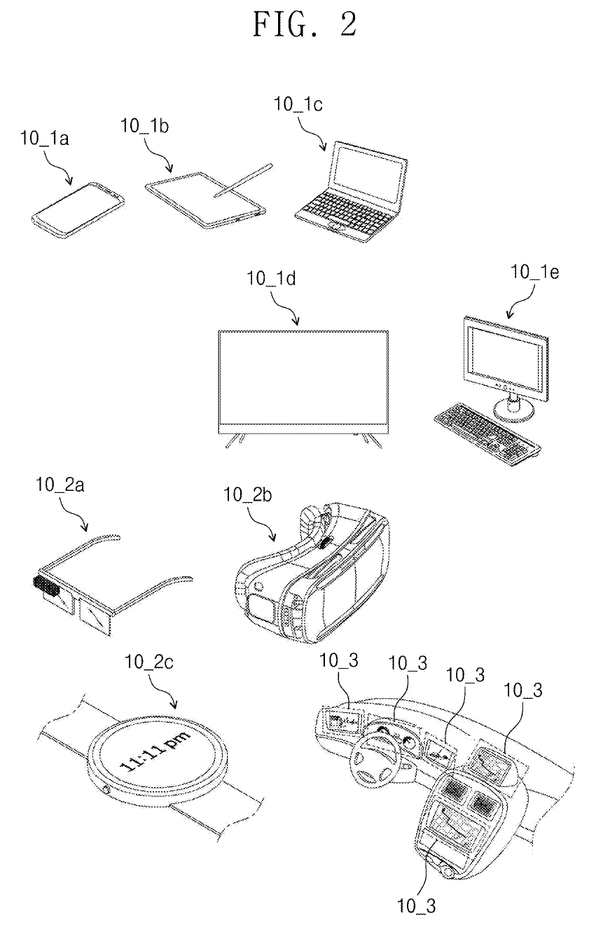

FIG. 2 illustrates perspective views of electronic devices according to various embodiments.

Referring to FIG. 2, various electronic devices, to which display devices according to embodiments are applied, may include not only an image-displaying electronic device, such as a smart phone 10_1a, a tablet PC 10_1b, a laptop 10_1c, a TV 10_1d, or a desk monitor 10_1e, but also a wearable electronic device including a display module, such as smart glasses 10_2a, a head-mounted display 10_2b, or a smart watch 10_2c, and a vehicular electronic device 10_3 including a display module, such as a car dashboard, a center fascia, a center information display (CID) disposed in a dashboard, or a room mirror display.

Hereinafter, a display device according to an embodiment of the inventive concept and an electronic device including the display device are described with reference to the drawings.

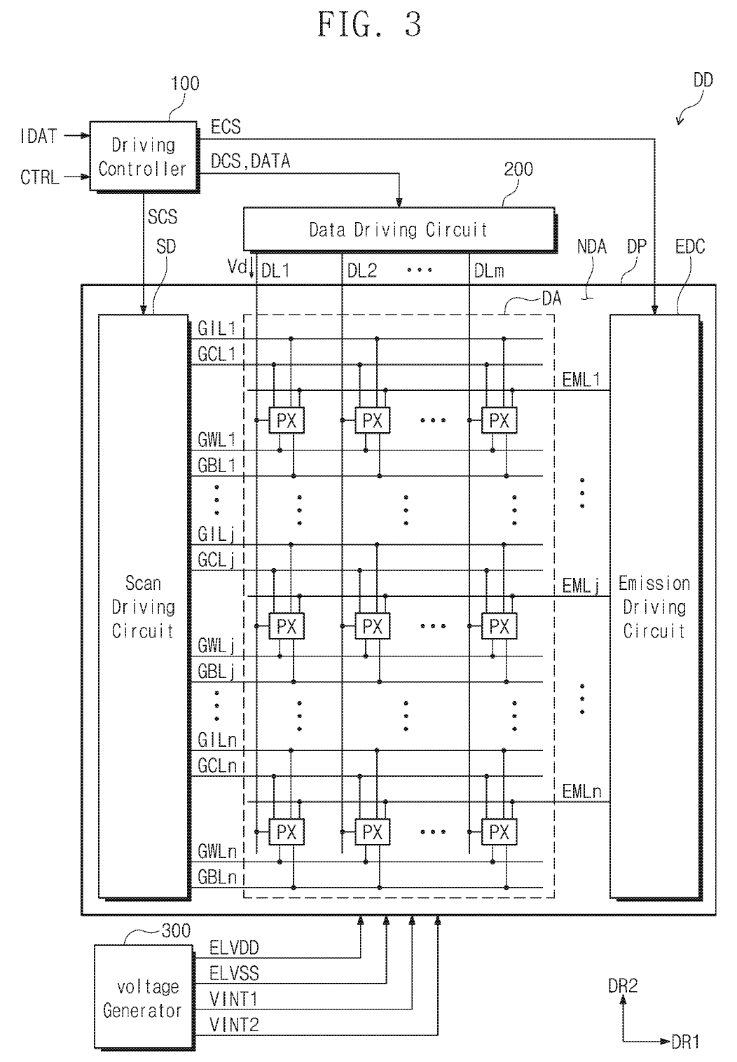

FIG. 3 is a block diagram illustrating a display device according to an embodiment of the inventive concept.

Referring to FIG. 3, the electronic device 10 (see FIG. 1) may include a display device DD.

The display device DD may be activated in response to an electrical signal and display an image. The display device DD may be implemented in various forms. For example, the display device DD may include not only a large-sized device such as a television, an outdoor billboard, but also a small- and medium-sized device such as a monitor, a mobile phone, a tablet computer, a navigation system, and a game console. It should be noted that the embodiments of the display device DD described herein are merely illustrative, and the inventive concept is not limited to any particular type of the display device as long as it falls within the scope and spirit of the inventive concept.

The display device DD according to an embodiment includes a display panel DP, a driving controller 100, a data driving circuit 200, and a voltage generator 300.

The driving controller 100 may receive image data IDAT and a control signal CTRL from an external host processor (for example, an application processor (AP), a graphic processing unit (GPU), or a graphic card). The processor 12 (see FIG. 1) may include a host processor. In an embodiment, the image data IDAT may include RGB data including red image data, green image data, and blue image data. Additionally, in an embodiment, the control signal CTRL may include a vertical synchronization signal, a horizontal synchronization signal, an input data enable signal, a master clock signal, and the like. However, the types included in the image data IDAT and the control signal CTRL are not limited thereto.

The driving controller 100 may further include an oscillator. The oscillator may generate a clock signal. Since the driving controller 100 has an internal oscillator, the driving controller 100 of the inventive concept may internally synchronize the display panel DP without receiving an external synchronization signal.

The host processor may provide information about a driving frequency (or a variable frame rate), which is included in the image data IDATA, to the driving controller 100, and the driving controller 100 according to an embodiment of the inventive concept may receive the image data IDAT including the driving frequency from the host processor. In an embodiment, the driving frequency may be variable. The driving controller 100 may control the data driving circuit 200, a scan driving circuit SD, and an emission driving circuit EDC to drive the display panel DP at the driving frequency.

The driving controller 100 may drive the display panel DP. The driving controller 100 receives the image data IDAT and the control signal CTRL. The driving controller 100 generates source data DATA obtained by converting the data format of the image data IDAT to comply with the interface specification of the data driving circuit 200. The driving controller 100 outputs a scan control signal SCS, a data control signal DCS, and an emission driving signal ECS.

The data driving circuit 200 receives the data control signal DCS and the source data DATA from the driving controller 100. The data driving circuit 200 converts the source data DATA into data signals Vd and outputs the data signals Vd to a plurality of data lines DL1 to DLm, which will be described later. The data signals Vd represent analog voltages corresponding to grayscale values of the source data DATA.

The voltage generator 300 generates voltages required for an operation of the display panel DP. In this embodiment, the voltage generator 300 generates a first driving voltage ELVDD, a second driving voltage ELVSS, a first initialization voltage VINT1, and a second initialization voltage VINT2.

The display panel DP according to an embodiment of the inventive concept may be a light-emitting display panel. However, the types of the display panel DP is not particularly limited thereto. For example, the display panel DP may be an organic light-emitting display panel, an inorganic light-emitting display panel, a micro-LED display panel, or a nano-LED display panel. A light-emitting layer of the organic light-emitting display panel may include an organic light-emitting material. A light-emitting layer of the inorganic light-emitting display panel may include quantum dots, quantum rods, or the like. A light-emitting layer of the micro-LED display panel may include a micro-LED. A light-emitting layer of the nano-LED display panel may include a nano-LED.

The display panel DP includes scan lines GIL1 to GILn, GCL1 to GCLn, GWL1 to GWLn, and GBL1 to GBLn, emission control lines EML1 to EMLn, data lines DL1 to DLm, and pixels PX. The display panel DP may further include the scan driving circuit SD and the emission driving circuit EDC. The display panel DP may display an image through the pixels PX which respectively receive corresponding scan signals from the scan lines GIL1 to GILn, GCL1 to GCLn, GWL1 to GWLn, and GBL1 to GBLn, emission control signals from the emission control lines EML1 to EMLn, and the data signals Vd from the data lines DL1 to DLm.

The display panel DP may be divided into a display region DA and a non-display region NDA surrounding at least a portion of the display region DA. Pixels PX may be disposed in the display region DA. The scan driving circuit SD and the emission driving circuit EDC may be disposed in the non-display region NDA.

In an embodiment, the scan driving circuit SD may be arranged on a first side of the display panel DP. The scan lines GIL1 to GILn, GCL1 to GCLn, GWL1 to GWLn, and GBL1 to GBLn extend in a first direction DR1 from the scan driving circuit SD.

The emission driving circuit EDC may be arranged on a second side of the display panel DP. The emission control lines EML1 to EMLn extend from the emission driving circuit EDC in a direction opposite to the first direction DR1. The emission driving circuit EDC receives the emission driving signal ECS from the driving controller 100 and outputs emission control signals to the emission control lines EML1 to EMLn.

The scan lines GIL1 to GILn, GCL1 to GCLn, GWL1 to GWLn, and GBL1 to GBLn, and the emission control lines EML1 to EMLn are arranged spaced apart from each other in a second direction DR2. The data lines DL1 to DLm extend from the data driving circuit 200 in a direction opposite to the second direction DR2 and are arranged spaced apart from each other in the first direction DR1.

Each of the plurality of pixels PX is electrically connected to the scan lines GIL1 to GILn, GCL1 to GCLn, GWL1 to GWLn, and GBL1 to GBLn, the emission control lines EML1 to EMLn, and the data lines DL1 to DLm. Each of the plurality of pixels PX may be electrically connected to four scan lines and one emission control line. For example, as illustrated in FIG. 3, the pixels in a first row may be connected to the scan lines GIL1, GCL1, GWL1, and GBL1, and the emission control line EML1. Additionally, the pixels in a Jth row may be connected to the scan lines GILj, GCLj, GWLj, and GBLj, and the emission control line EMLj.

Each of the plurality of pixels PX receives the first driving voltage ELVDD, the second driving voltage ELVSS, the first initialization voltage VINT1, and the second initialization voltage VINT2 from the voltage generator 300.

The scan driving circuit SD receives the scan control signal SCS from the driving controller 100. The scan driving circuit SD may output scan signals to the scan lines GIL1 to GILn, GCL1 to GCLn, GWL1 to GWLn, and GBL1 to GBLn in response to the scan control signal SCS.

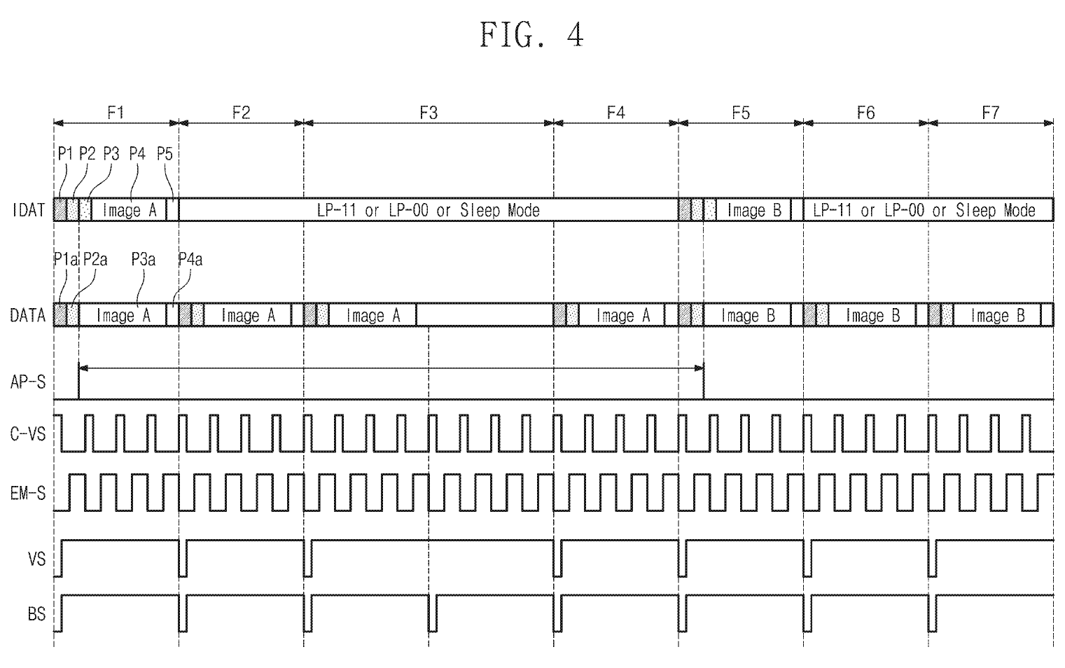

FIG. 4 illustrates a diving frequency, image data, source data, and synchronization signals associated with a driving operation of an electronic device according to an embodiment of the inventive concept.

Referring to FIGS. 1, 3, and 4, the display panel DP may operate on a frame-by-frame basis. A plurality of frames are provided, and each of plurality of frames F1 to F7 may operate in accordance with a corresponding driving frequency. In at least one frame, the image data IDAT may include a plurality of sections which are arranged sequentially. For example, the image data IDAT for at least one frame may include a first section P1, a second section P2, a third section P3, a fourth section P4, and a fifth section P5, which are arranged sequentially. Furthermore, the source data DATA in each of the plurality of frames F1 to F7 may include a first source section P1a, a second source section P2a, a third source section P3a, and a fourth source section P4a, which are arranged sequentially.

The plurality of frames F1 to F7 may include a first frame F1, a second frame F2, a third frame F3, a fourth frame F4, a fifth frame F5, a sixth frame F6, and a seventh frame F7. The first frame F1 may be driven in a first driving frequency. The second frame F2 may be driven in a second driving frequency. The third frame F3 may be driven in a third driving frequency. The fourth frame F4 may be driven in a fourth driving frequency. The fifth frame F5 may be driven in a fifth driving frequency. The sixth frame F6 may be driven in a sixth driving frequency. The seventh frame F7 may be driven in a seventh driving frequency. For example, the first frame F1, the second frame F2, the fourth frame F4, the fifth frame F5, the sixth frame F6, and the seventh frame F7 may operate at 120 Hz, and the third frame F3 may operate at 60 Hz.

The image data IDAT may include not only information representing the image but also information indicating a state in which an operation is performed. The information representing the image may include a first image Image A and a second image Image B. The information indicating a state in which an operation is performed may include, for example, a first mode LP-11, a second mode LP-00, and a third mode Sleep Mode. The first mode LP-11 may represent a standby state in which no image data IDAT is output through an interface between the processor 12 and the display panel DP. The second mode LP-00 may represent a preparation state in which the interface between the processor 12 and the display panel DP is ready for outputting the image data IDAT. The third mode Sleep Mode may represent a power-saving state in which no image data IDAT is output from the processor 12, and the display panel DP remains in a power-saving state.

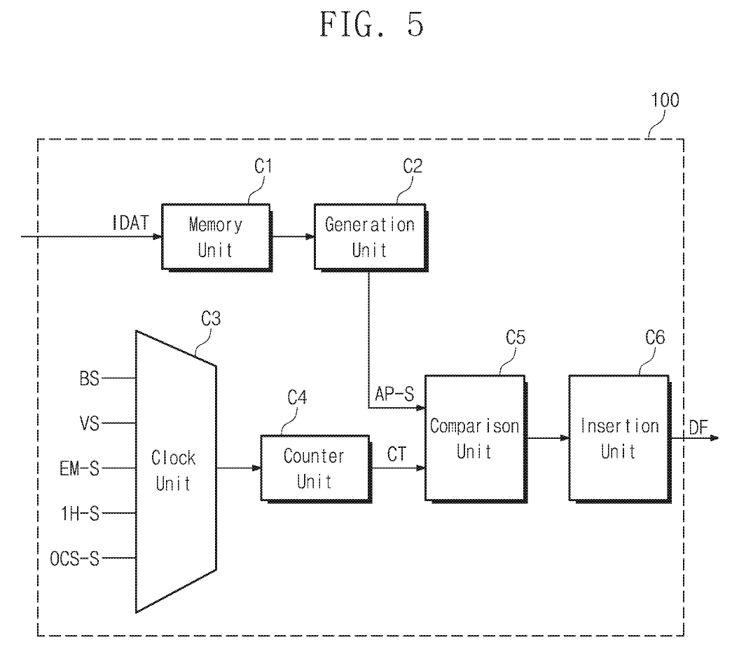

The first section P1 may indicate the start of each of the plurality of frames F1 to F7. The second section P2 may serve to prepare the plurality of frames F1 to F7. In the third section P3, command data may be provided. The command data may include a message to store, in accordance with a command of the processor 12, the information representing the image in a memory unit C1 (see FIG. 5) of the driving controller 100. For example, the command data may be provided before the first image Image A is provided and before the second image Image B is provided. In the fourth section P4, the information representing the image may be provided. For example, the first image Image A and the second image Image B may be provided to the display panel DP during the fourth section P4. The information representing the image is not limited to any particular information unless departing from the scope and spirit of the inventive concept. The fifth section P5 may serve to stabilize the frame.

During each of the plurality of frames F1 to F7, the driving controller 100 may provide the first image Image A or the second image Image B in the form of the source data DATA to the display panel DP, so as to display the corresponding first image Image A or the second Image B stored in the memory unit C1 (see FIG. 5).

The first source section P1a may indicate the start of each of the frames F1 to F7. The first source section P1a may be output in accordance with a clock pulse of a vertical synchronization signal. The first source section P1a may correspond to the first section P1 of the image data IDAT. The second source section P2a may serve to prepare the frame. The second source section P2a may correspond to the second section P2 of the image data IDAT. The information representing the image may be provided in the third source section P3a. The third source section P3a may correspond to the fourth section P4 of the image data IDAT. The fourth source section P4a may serve to stabilize the frame. The fourth source section P4a may correspond to the fifth section P5 of the image data IDAT.

The driving controller 100 may adjust the length of the fourth source section P4a of the source data DATA and determine the driving frequency of each of the plurality of frames F1 to F7. For example, the length of the fourth source section P4a provided in the first frame F1 may be different from the length of the fourth source section P4a provided in the third frame F3. For example, the length of the fourth source section P4a provided in the third frame F3 is longer than the length of the fourth source section P4a provided in the first frame F1, so as to drive the third frame F3 in the lower driving frequency than the first frame F1.

According to the inventive concept, when driving frequencies are different from one another, the length of the fourth source section P4a may be adjusted to make the operations performed at the same frequency. For example, the first frame F1 may operate at 120 Hz, and the third frame F3 may operate at 60 Hz. The fourth source section P4a may be extended so that the third frame F3 is driven in a lower driving frequency than the first frame F1.

The display device DD may operate in a driving section and a scan section. The display device DD may control the driving frequency of the display panel DP by extending the scan section. In an embodiment, the driving section may include the first to third source sections P1a, P2a, and P3a, and the scan section may include the fourth source section P4a. For example, the fourth source section P4a may be extended so that the third frame F3 and the first frame F1 are driven in the same frequency. The display device DD may synchronize the frame generation performed by the processor 12 included in the display device DD with the frame output timing of the display panel DP. That is, the display panel DP may operate at a variable frequency, which may be referred to as operating in a variable frequency mode. For example, the power consumption of the display device DD may decrease by lowering the driving frequency of the display device DD when displaying a still image.

The data driving circuit 200 may generate a data signal Vd based on the first image Image A or the second image Image B of the source data DATA.

The driving section may represent a period during which the plurality of pixels PX receive the data signal Vd and emit light, and the scan section may represent a period during which the plurality of pixels PX keep emitting light without receiving the data signal Vd.

The driving controller 100 may generate a command synchronization signal AP-S. The command synchronization signal AP-S may output a clock pulse each time the command data is input during the third section P3.

An external synchronization signal C-VS is generated based on a clock signal generated by the processor 12. The external synchronization signal C-VS may be a clock signal that repeats in a first period.

An emission synchronization signal EM-S is a synchronization signal that controls an emission timing of the plurality of pixels PX in the display panel DP. The emission synchronization signal EM-S may determine an emission start time point and an emission duration of the plurality of pixels PX in each frame. The emission synchronization signal EM-S may control the emission timing of each of the plurality of pixels PX. By determining the ON/OFF timing of the current supplied to the plurality of pixels PX, the emission or the non-emission of the plurality of pixels PX within a specific frame section can be controlled. Additionally, the emission synchronization signal EM-S may be varied according to the scan rate and the driving scheme of the display panel DP, and may contribute to the optimization of display quality and power consumption by adjusting an emission pattern during a specific frame period.

The emission synchronization signal EM-S may be a clock signal that repeats in a second period different from the first period.

A vertical synchronization signal VS indicates a start of each of the plurality of frames F1 to F7. The vertical synchronization signal VS may be used as a signal which indicates that the next frame is ready to be output upon completion of the current frame. The period of the vertical synchronization signal VS may be determined according to the driving frequency of each of the plurality of frames F1 to F7.

A basic synchronization signal BS is generally used as a reference signal corresponding to the maximum driving frequency of the display panel DP. For example, the maximum driving frequency of the display panel DP may be about 120 Hz. The basic synchronization signal BS may be a clock signal that repeats in a third period which is different from the first period and the second period.

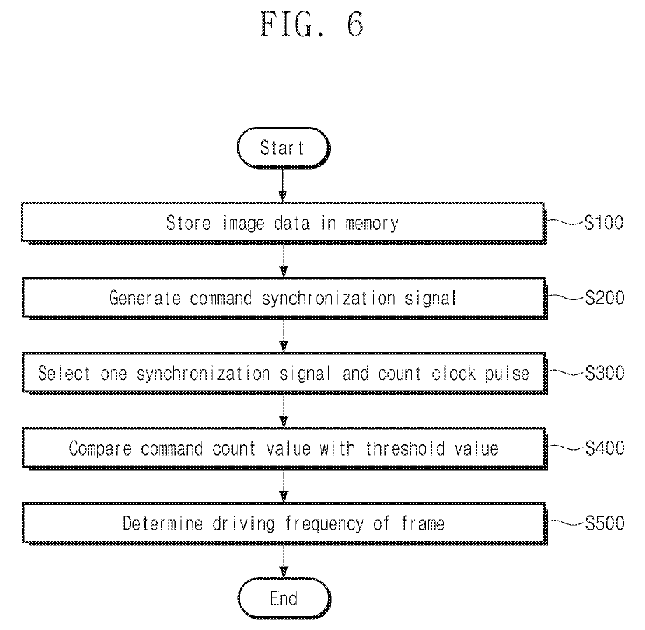

FIG. 5 is a block diagram illustrating a driving controller according to an embodiment of the inventive concept, and FIG. 6 is a flowchart illustrating a method of driving an electronic device according to an embodiment of the inventive concept.

Referring to FIGS. 3, 4, 5, and 6, the driving controller 100 may include the memory unit C1, a generation unit C2, a clock unit C3, a counter unit C4, a comparison unit C5, and an insertion unit C6.

The image data IDAT received from the outside may be stored in the memory unit C1 (S100). For example, the memory unit C1 may store the image data IDAT, including the first image Image A or the second image B, in response to the command received during the third section P3.

The generation unit C2 may generate the command synchronization signal AP-S based on the command data of the third section P3, which makes the image data IDAT be stored in the memory unit C1 (S200). A clock pulse of the command synchronization signal AP-S may be output when the command data of the third section P3 is input. For example, as depicted in FIG. 4 above, when the third section P3 corresponding to the first frame F1 is input, a high pulse of the command synchronization signal AP-S may be output, and when the third section P3 corresponding to the fifth frame F5 is input, a high pulse of the command synchronization signal AP-S may be output.

The clock unit C3 may select one synchronization signal among a plurality of synchronization signals BS, VS, EM-S, 1H-S, and OCS-S, and the counter unit C4 may count clock pulses of the synchronization signal and output a count value CT (S300).

The plurality of synchronization signals described above may include the basic synchronization signal BS, the vertical synchronization signal VS, the emission synchronization signal EM-S, a horizontal synchronization signal 1H-S, and an oscillator synchronization signal OCS-S which have different periods from one another. However, this is an example, and the types of the plurality of synchronization signals according to an embodiment of the inventive concept are not limited thereto.

The oscillator synchronization signal OCS-S may control logic operations and timings based on a clock signal generated from an oscillator of the driving controller 100. The oscillator synchronization signal OCS-S may control the driving controller 100 to perform the logic operations by referring to the clock signal, and may ensure the accuracy of data transmission, signal processing, and panel driving by adjusting the period and timing of the signal. Additionally, the oscillator synchronization signal OCS-S may maintain the operation of the internal circuit at a certain frequency, thereby enabling stable control of the overall system operations of the driving controller 100.

The comparison unit C5 may receive the command synchronization signal AP-S and the count value CT. The comparison unit C5 may calculate a command count value based on the count value CT during a period of the command synchronization signal AP-S, and compare the command count value with a threshold value (S400).

The command count value may be a value obtained by counting the number of clock pulses of the synchronization signal (e.g., the count value CT), which is selected as one synchronization signal by the clock unit C3, during a period of the command synchronization signal AP-S, which is a period between two adjacent pulses of the command synchronization signal AP-S. For example, if the basic synchronization signal BS is selected as one synchronization signal by the clock unit C3, the command count value, which is the value obtained by counting the number of clock pulses of the basic synchronization signal BS during the period of the command synchronization signal AP-S, may be 5. The threshold value is not a fixed value and may be set arbitrarily. For example, when the threshold value is set to 1, the comparison unit may compare the command count value with the threshold value. In this case, since the command count value of 5 is greater than the threshold value of 1, the comparison unit C5 may provide a command to the insertion unit C6 to insert the first image Image A or the second image Image B by controlling the driving frequency.

A step of determining the driving frequency of the frame (S500) may be followed the step of comparing the command count value with the threshold value (S400), if the command count value is greater than the threshold value. For example, the comparison unit C5 may compare the command count value with the threshold value, and the insertion unit C6 may determine the driving frequency if the command count value is greater than the threshold value. For example, when the comparison unit C5 determines that the command count value is greater than the threshold value, the insertion unit C6 may determine the driving frequency, and the driving controller 100 may output source data DATA based on image data IDAT stored in the memory unit C1. In contrast, when the command count value is not greater than the threshold value, the insertion unit C6 may not determine the driving frequency, and the driving controller 100 may not output the source data DATA.

In a comparative example, the driving controller may count the length of the fourth source section P4a and compare the count value of the length of the fourth source section P4a with the threshold value. However, in this case, if the second image Image B is newly input after the fourth frame F4, which continues displaying the first image Image A and operates at a driving frequency of 120 Hz, the length of the fourth source section P4a of the fourth frame F4, which immediately precedes the new image data, may be less than the threshold value. Although the first image Image A is continuously displayed from the first frame F1 to the fourth frame F4, which may cause occurrence of an afterimage, the driving controller may display the second image Image B without adjusting the driving frequency of the subsequent frames. As a result, an afterimage of the first image Image A may occur in the comparative example. However, according to the inventive concept, the driving controller 100 counts the number of synchronization signal selected by the clock unit C3 during a period of the command synchronization signal AP-S (e.g., a period between two adjacent pulses of the command synchronization signal AP-S) and compares the count value with the threshold value. Since the command synchronization signal AP-S is generated regardless of the fourth source section P4a and the driving frequency, the insertion unit C6 may control the driving frequency of the subsequent frames F5, F6, and F7 so as to repeatedly output the second image Image B, even when the first image Image A is maintained and the second image Image B is then input. For example, the insertion unit C6 may control the driving frequency of the subsequent frames F5, F6, and F7 at 120 Hz, thereby preventing or removing the afterimage of the first image Image A. Accordingly, the afterimage associated with previously displayed image data may be prevented, and the electronic device 10 (see FIG. 1) having an improved display quality may be provided.

The comparison unit C5 may further compare the value stored in the memory unit C1 with the value newly input into the memory unit C1. If the comparison unit C5 determines that the value stored in the memory unit C1 is not equal to the newly input value, the insertion unit C6 may determine the driving frequency of the frame. The value stored in the memory unit C1 or newly input into the memory unit C1 may be the information representing the image. For example, when the same first image A is newly input into the memory unit C1, which stores the previously provided first image A, the insertion unit C6 may not determine the driving frequency of the frame, and the driving controller 100 may not output the source data DATA. In contrast, when the second image Image B is newly input into the memory unit C1 in which the first image A is stored, the insertion unit C6 may determine the driving frequency of the frame, and the driving controller 100 may output the source data DATA.

The insertion unit C6 may determine the driving frequency of the frame (S500). The driving controller 100 may output the source data DATA on the basis of the image data IDAT stored in the memory unit C1 when the command count value is greater than the threshold value or when the value stored in the memory unit C1 is not equal to the newly input value. The driving controller 100 may also output the source data DATA on the basis of the image data IDAT stored in the memory unit C1 when the command count value is greater than the threshold value.

According to the description above, a driving controller counts the number of synchronization signal, which is selected as one synchronization signal selected by a clock unit, during a period of a command synchronization signal, and compares the count value (e.g., the command count value which is explained above) with a threshold value. Furthermore, an insertion unit of the driving controller may repeatedly output the new image by controlling a driving frequency of subsequent frames. For example, the insertion unit may prevent or remove an afterimage of the previously displayed image data by controlling the driving frequency of the subsequent frames at 120 Hz. Therefore, the afterimage of the previously displayed image data may be prevented, and an electronic device having an improved display quality may be provided.

In the above, description has been made with reference to embodiments of the inventive concept, but those skilled or of ordinary skill in the art may understand that various modifications and changes can be made to the inventive concept insofar as such modifications and changes fall within the spirit and technical feature of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a display panel configured to display an image on a frame-by-frame basis; and
a driving controller configured to drive the display panel and receive image data including command data,
wherein the driving controller includes,
a memory unit configured to store the image data based on the command data,
a generation unit configured to generate a command synchronization signal in response to the command data,
a clock unit configured to select a synchronization signal among a plurality of synchronization signals,
a counter unit configured to count clock pulses of the synchronization signal and output a count value,
a comparison unit configured to calculate a command count value and compare the command count value with a threshold value, the command count value being calculated by counting a number of the clock pulses of the synchronization signal during a period of the command synchronization signal, and
an insertion unit configured to determine a driving frequency of the frame based on the comparison of the command count value and the threshold value, and
wherein the driving controller is configured to output source data based on the image data stored in the memory unit when the command count value is greater than the threshold value.

2. The electronic device of claim 1, wherein the plurality of synchronization signals comprise a basic synchronization signal, a vertical synchronization signal, an emission synchronization signal, a horizontal synchronization signal, and an oscillator synchronization signal, and
each of the plurality of synchronization signals has a period different from one another.

3. The electronic device of claim 2, wherein the display panel comprises a pixel, and the emission synchronization signal controls an emission of the pixel.

4. The electronic device of claim 2, wherein the driving controller further comprises an oscillator, and
the oscillator synchronization signal controls a logic operation and timing based on a clock signal generated from the oscillator.

5. The electronic device of claim 1, wherein the command synchronization signal is configured to output a clock pulse when the command data is input.

6. The electronic device of claim 1, wherein the image data of the frame comprises a first section, a second section, a third section, a fourth section, and a fifth section, which are arranged sequentially, and
the first section indicates a start of the frame.

7. The electronic device of claim 6, wherein the second section is configured to serve to prepare the frame.

8. The electronic device of claim 6, wherein the command data is provided in the third section.

9. The electronic device of claim 6, wherein information representing the image is provided in the fourth section.

10. The electronic device of claim 6, wherein the fifth section is configured to serve to stabilize the frame.

11. The electronic device of claim 2, wherein the source data of the frame comprises a first source section, a second source section, a third source section, and a fourth source section, which are arranged sequentially, and
the first source section indicates a start of the frame in response to a clock pulse of the vertical synchronization signal.

12. The electronic device of claim 11, wherein the second source section is configured to serve to prepare the frame.

13. The electronic device of claim 11, wherein information representing the image is provided in the third source section.

14. The electronic device of claim 11, wherein the fourth source section is configured to serve to stabilize the frame,
the frame includes a first frame having a first driving frequency and a second frame having a second driving frequency different from the first driving frequency, and
a length of the fourth source section provided in the first frame is different from a length of the fourth source section provided in the second frame.

15. A method of driving an electronic device which includes a display panel configured to display an image on a frame-by-frame basis, and a driving controller configured to drive the display panel and receive image data including command data, the method comprising:
storing the image data in a memory unit;
generating a command synchronization signal based on the command data;
selecting a synchronization signal and counting clock pulses of the synchronization signal;
calculating a command count value and comparing the command count value with a threshold value; and
determining a driving frequency of the frame,
wherein the command count value is calculated by counting a number of the clock pulses of the synchronization signal during a period of the command synchronization signal.

16. The method of claim 15, wherein the command synchronization signal is configured to output a clock pulse when the command data is input.

17. The method of claim 15, wherein the determining of a driving frequency of the frame further includes outputting source data based on the image data stored in the memory unit when the command count value is greater than the threshold value.

18. The method of claim 15, further comprising comparing a value stored in the memory with a value which is newly input into the memory unit.

19. The method of claim 18, wherein the determining of a driving frequency of the frame is performed when the value stored in the memory is not equal to the value which is newly input into the memory unit.

20. The method of claim 15, wherein the driving controller outputs source data based on the image data stored in the memory unit when the command count value is greater than the threshold value or a value stored in the memory is not equal to a value which is newly input.
